(19) United States
(12) Patent Application Publication
(10) Pub. No.: US 2004/0063287 A1
(43) Pub. Date: Apr. 1, 2004

(54) Semiconductor device and method of manufacturing the same

(76) Inventors: Dong-Hyun Kim, Gyeonggi-do (KR); Tae-Hyuk Ahn, Gyeonggi-do (KR); Jong-Seo Hong, Gyeonggi-do (KR); Min-Ho Kim, Gyeonggi-do (KR)

Correspondence Address: MARGER JOHNSON & McCOLLOM, P.C., 1030 S.W. Morrison Street, Portland, OR, 97205, US

(21) Appl. No.: 10/452,674

(22) Filed: May 30, 2003

(30) Foreign Application Priority Data
Sep. 26, 2002 (KR) 2002-58426

(51) Int. Cl. H01L 21/336

(52) U.S. Cl. 438/296

(57) ABSTRACT

In a semiconductor device capable of reducing operation fails and a method of manufacturing the same, gate structures and source/drain regions are formed on a semiconductor substrate. Nitride spacers are formed on both sidewalls of each of the gate structures. A first insulating interlayer is formed to cover the gate structures. Source pad electrodes are formed in each of the first contact holes and connected to the exposed source regions. A second insulating interlayer is formed on the first insulating interlayer. Metal lines for signal transmission are formed on the second insulating interlayer so as to make direct contact with the drain region of each group to electrically connect the drain regions with each other, while being isolated from the source pad electrodes.

### BACKGROUND OF THE INVENTION

1. Field of the Invention

The present disclosure relates to a semiconductor device and a method of manufacturing the same. More particularly, the disclosure invention relates to a semiconductor device including transistors and a method of manufacturing the same.

2. Description of the Related Art

In the information society of these days, semiconductor devices are making rapid progress with the rapid spread of information media such as a computer. It requires that the semiconductor devices operate at a high speed and have large storage capacity. In order to satisfy these demands, manufacturing technology of the semiconductor device has been developed as it enhances integration degree, reliability and response speed. Particularly, feature sizes of patterns formed on a semiconductor chip and the space between the patterns are becoming smaller and smaller so as to increase the integration degree of the semiconductor device.

Semiconductor memory devices such as DRAM, SRAM or NVM include one or more transistor in one memory element (hereinafter, referred to as “cell”). In these memory devices, a horizontal size of the transistor greatly affects the integration degree. So, processing technology of the memory device is developed to scale down gate lengths and source/drain regions of the transistor.

However, with the scaling down of the transistor size, there are generated unexpected process failures that did not occur formerly. Further, it is difficult to obtain the reproducible operation characteristics of the transistor because the operation characteristics of the transistor vary largely with a little difference in processes. Hereinafter, the process failures will be described with reference to a manufacturing process of a transistor including a pad electrode connected source/drain regions as an example.

FIGS. 1A to 1E are cross-sectional views illustrating a conventional, or prior art, method of forming transistors including pad electrodes.

Referring to FIG. 1A, gate structures 18 are formed on a silicon substrate 10. Each of the gate structures 18 includes a gate oxide layer pattern 12, a conductive layer pattern 14 and a nitride layer pattern 16 that are stacked successively.

Next, using the gate structures 18 as a mask, impurity ions are implanted below the surface of the substrate 18 to thereby form source and drain regions 20a and 20b at the surface portions of the substrate 10.

Then, a nitride layer is uniformly deposited on the surface of the gate structures 18 and the substrate 10 and anisotropically etched to form nitride spacers 22 on the sidewalls of each of the gate structures 18.

Referring to FIG. 1B, a first insulating interlayer 24 comprising silicon oxide is formed so as to completely cover the gate structures 18 including the nitride spacers 22. Then, a portion of the first insulating interlayer 24 is etched away to form self-aligned contact holes 26 partially exposing the source and drain regions 20a and 20b.

Referring to FIG. 1C, a cleaning process using a chemical is executed on the substrate 10 on which the self-aligned contact holes 26 from FIG. B are formed, thereby removing polymers and native oxide layers formed on the bottom of the self-aligned contact holes 26. The cleaning process reduces a contact resistance between the source/drain regions 20a and 20b and a pad electrode to be formed in a subsequent process. However, the first insulating interlayer 24 exposed to the sides of the self-aligned contact holes 26, as well as the native oxide layers, is partially removed by the cleaning process.

Next, a polysilicon layer is formed so as to fill up each of the self-aligned contact holes 26 and etched back such that the polysilicon layer remains only within the self-aligned contact holes 26. As a result, there are formed pad electrodes 28a and 28b that make contact with the source/drain regions 20a and 20b.

However, a space d1 between the neighboring contact holes becomes small and narrow on each of the self-aligned contact holes 26 because the self-aligned contact hole 26 is formed such that the upper open region thereof is wider than the lower open region thereof. Accordingly, in case where the first insulating interlayer 24 adjacent to the upper portion of the self-aligned contact hole 28 is removed during the above described cleaning process, a problem may occur such that the neighboring pad electrodes 28b are connected to each other (see A in FIG. 2). This is referred to as a bridge failure here.

Further, the contact resistance between the pad electrodes 28a and 28b and the source/drain regions 20a and 20b increases because a size d2 of a portion where the source/drain regions 20a and 20b make contact with the pad electrodes 28a and 28b is very small. With the increase in the contact resistance, there are generated process failures such as the decrease in the operating speed of the semiconductor device, the operation failure, etc.

Referring to FIG. 1D, a second insulating interlayer 30 is formed on the pad electrodes 28a and 28b and then, partially etched away to form contact holes 32 exposing the upper surfaces of the pad electrode 28b connected to the drain regions 20b.

Referring to FIG. 1E, after filling the contact holes 32 with a conductive material, a portion of the conductive material formed on the second insulating interlayer 30 is etched away to form signal transmission lines 34 for connecting the pad electrodes 28b with each other, the pad electrodes 28b making contact with the drain regions 20b.

When forming the transistor, the above described process failures such as the bridge failure between the pad electrodes 28a and 28b and the operation failure caused by the increase in the contact resistance are frequently generated with the scaling down of the design rule of the semiconductor device. Accordingly, developing a process capable of minimizing such failures is necessary.

### SUMMARY OF THE INVENTION

In a first embodiment, gate structures are formed on a semiconductor substrate. Each of the gate structures has a gate insulating layer pattern, a conductive layer pattern and a nitride layer pattern that are stacked successively. Nitride spacers are formed on both sidewalls of each of the gate structures. Source/drain regions are formed below the surface of the substrate adjacent to both sidewalls of each of the gate structures. Over the resultant structure, there is formed a first insulating interlayer having first contact holes exposing the source regions. Source pad electrodes are formed in each of the first contact holes and connected to the corresponding source regions. A second insulating interlayer is formed on the first insulating interlayer. Metal lines for signal transmission are formed on the second insulating interlayer so as to fill up second contact holes that are formed to pass through the first and second insulating interlayer and to expose the drain regions.

There is also provided a method of manufacturing a semiconductor device comprising the step of forming gate structures on a semiconductor substrate, each of the gate structures including a gate insulating layer pattern, a conductive layer pattern and a nitride layer pattern that are stacked successively. Using the gate structures as a mask, an impurity is implanted below the surface of the substrate to form source and drain regions. Nitride spacers are formed on both sidewalls of each of the gate structures. A first insulating interlayer is formed to cover the gate structures. A portion of the first interlayer insulating is etched away to form first contact holes partially exposing the substrate portion where the source regions are formed. The first contact holes are filled up with a conductive material to form source pad electrodes under the source regions, each of the source pad electrodes making contact with each of the exposed source regions. A second insulating interlayer is formed on the first insulating interlayer. The second insulating interlayer and the first insulating interlayer are partially etched away to form second contact holes exposing the substrate portion where the drain regions are formed. A metal material is deposited in the second contact holes and on the second insulating interlayer. A portion of the metal material formed on the second insulating interlayer is etched to form metal lines for signal transmission. The metal lines make contact with the drain region of each group while being isolated from the source pad electrodes.

In one embodiment of the present invention, capacitors connected to the source pad electrodes may be formed on each of the source pad electrodes.

According to embodiments of the present invention, the semiconductor device includes the lines for signal transmission comprising the metal material and directly connected to the drain regions. So, a contact resistance between the drain region and the line for signal transmission can be minimized because the metal material has a relatively lower resistance than the other materials.

Further, the line for signal transmission is formed to be make direct contact with the drain region, thereby minimizing the generation of a bridge between the pad electrode and the line for signal transmission.

### BRIEF DESCRIPTION OF THE DRAWINGS

The above and other objects and advantages of the present invention will become readily apparent by reference to the following detailed description when considered in conjunction with the accompanying drawings wherein:

FIGS. 1A to 1E are cross-sectional views illustrating a conventional, or prior art, method of forming a transistor including a pad electrode;

FIG. 2 is a cross-sectional view showing failures generated in the conventional transistor;

FIG. 3 is a plane view of a DRAM device in accordance with one embodiment of the present invention;

FIG. 4 is a cross-sectional view of the DRAM device in accordance with one embodiment of the present invention; and

FIGS. 5A to 5I are cross-sectional views illustrating a method of manufacturing the DRAM device according to one embodiment of the present invention.

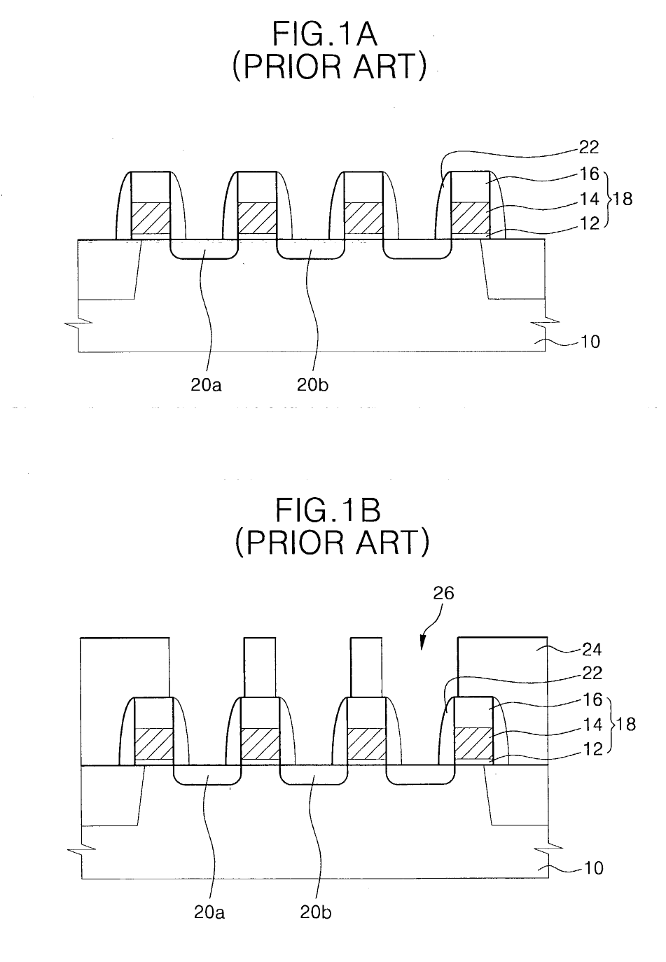

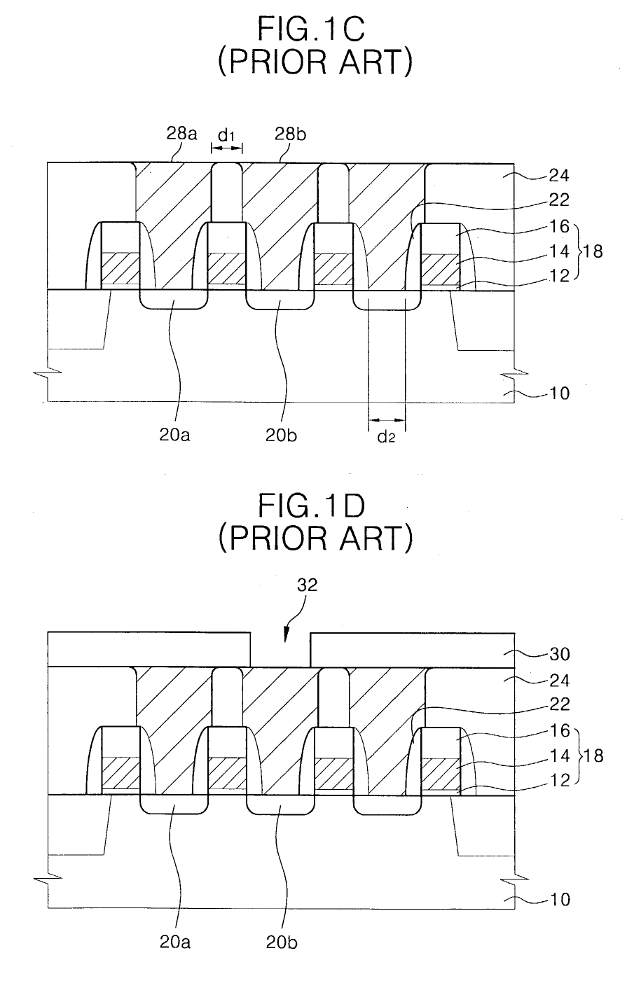

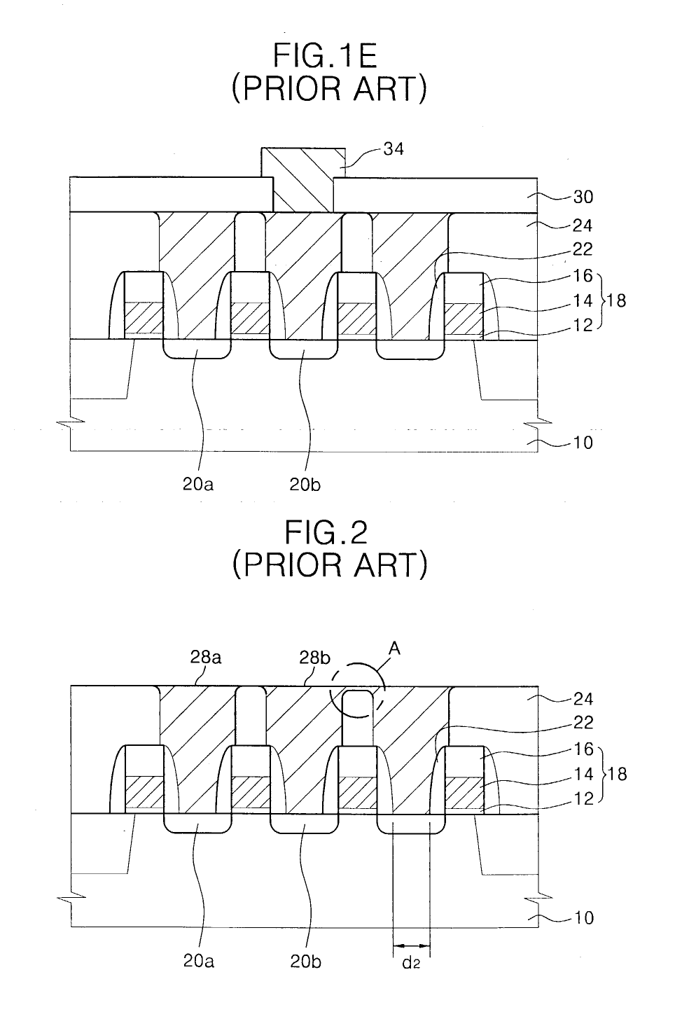

### DESCRIPTION OF THE PREFERRED EMBODIMENTS

Hereinafter, the preferred embodiments of the present invention will be described in detail with reference to the accompanying drawings. In the following drawings, the same numerals indicate the same elements.

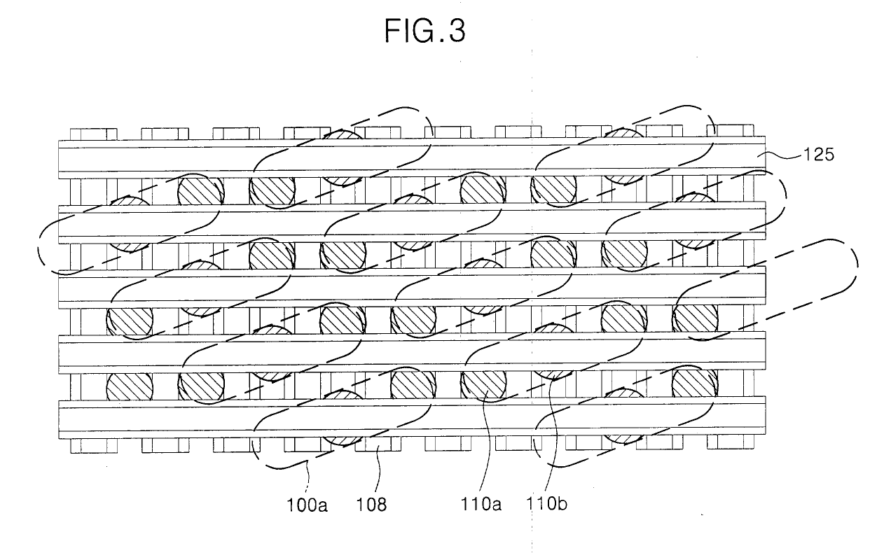

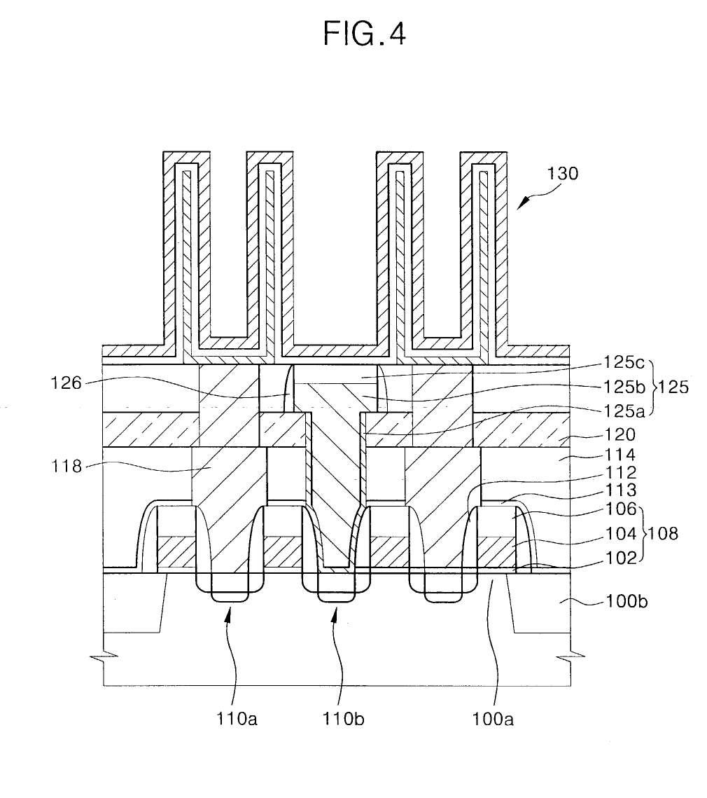

FIG. 3 is a plane view of a DRAM device in accordance with one embodiment of the present invention and particularly shows a memory cell layout capable of being applied to a DRAM device having a design rule of 0.2 um or less. FIG. 4 is a cross-sectional view of the DRAM device in accordance with one embodiment of the present invention.

Arrangement relation of elements constituting each cell of the DRAM device will be described with the reference to the FIG. 3.

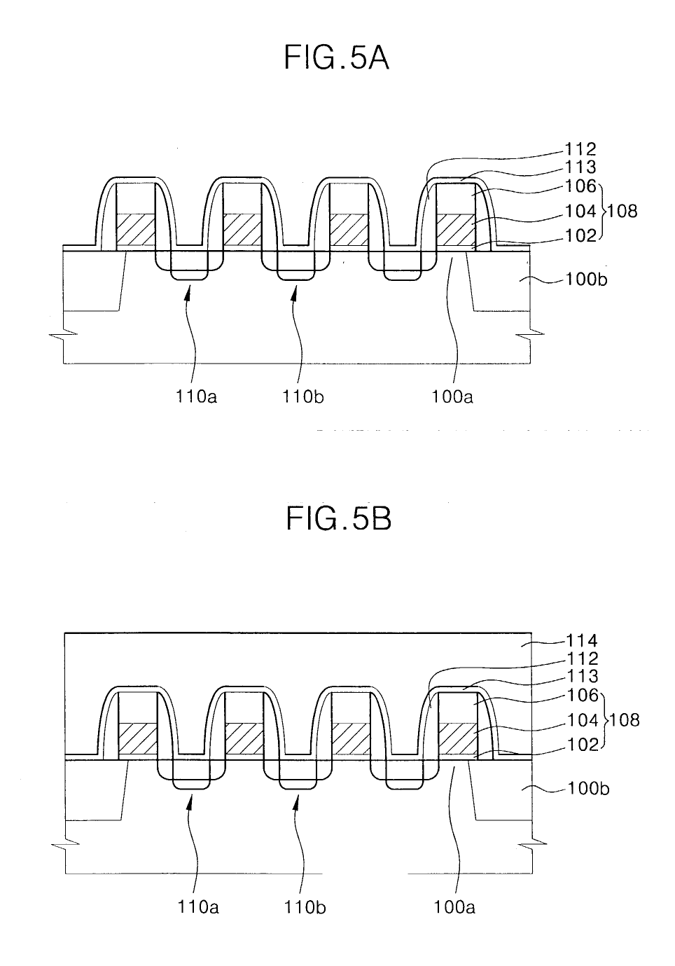

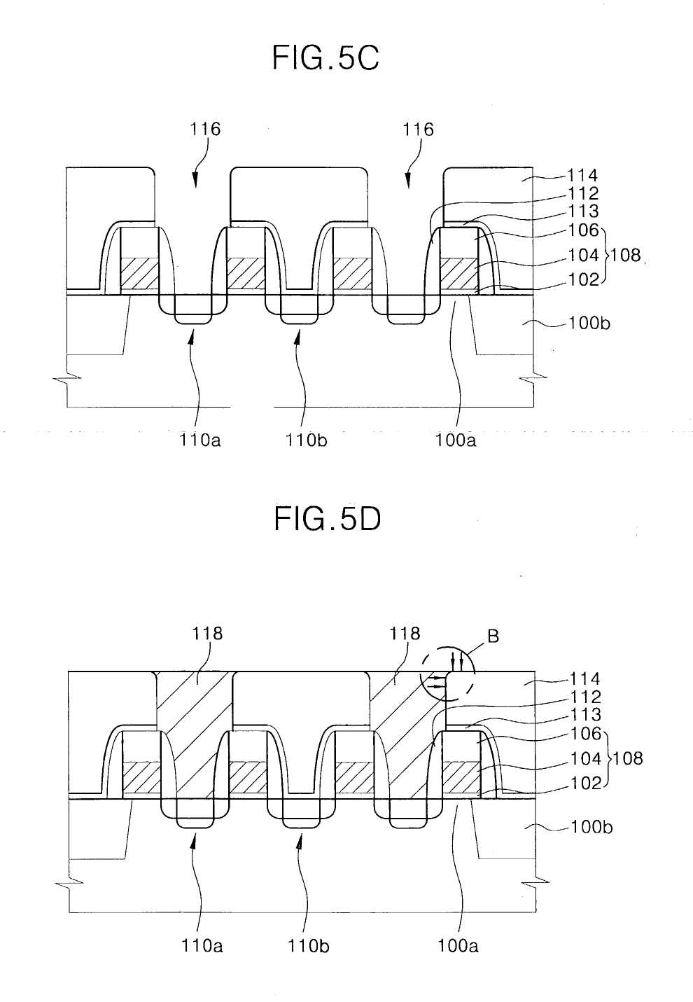

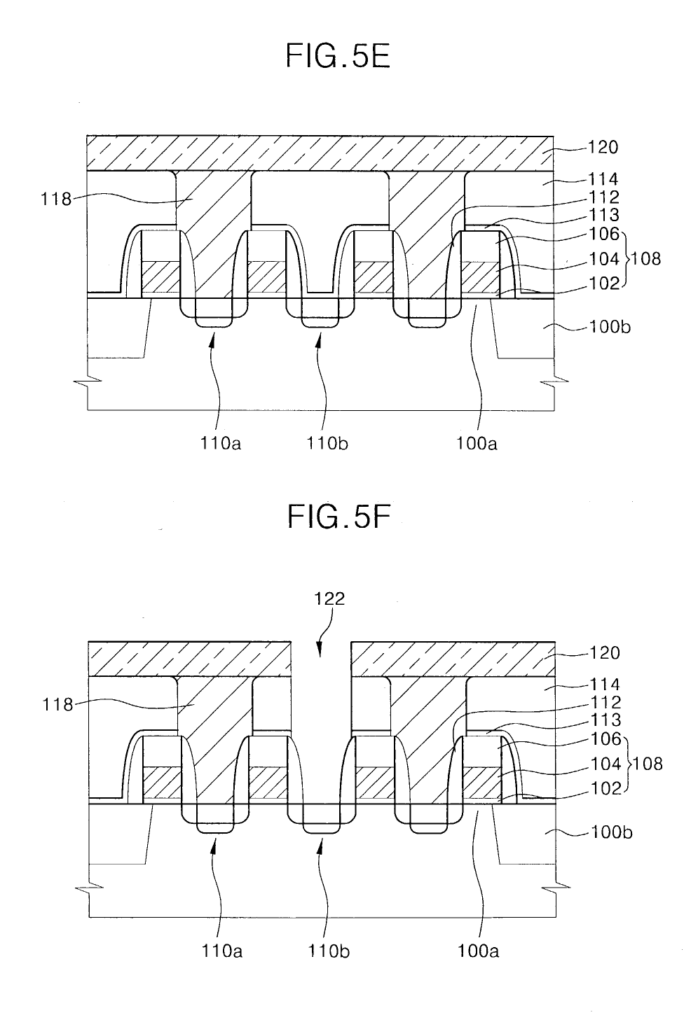

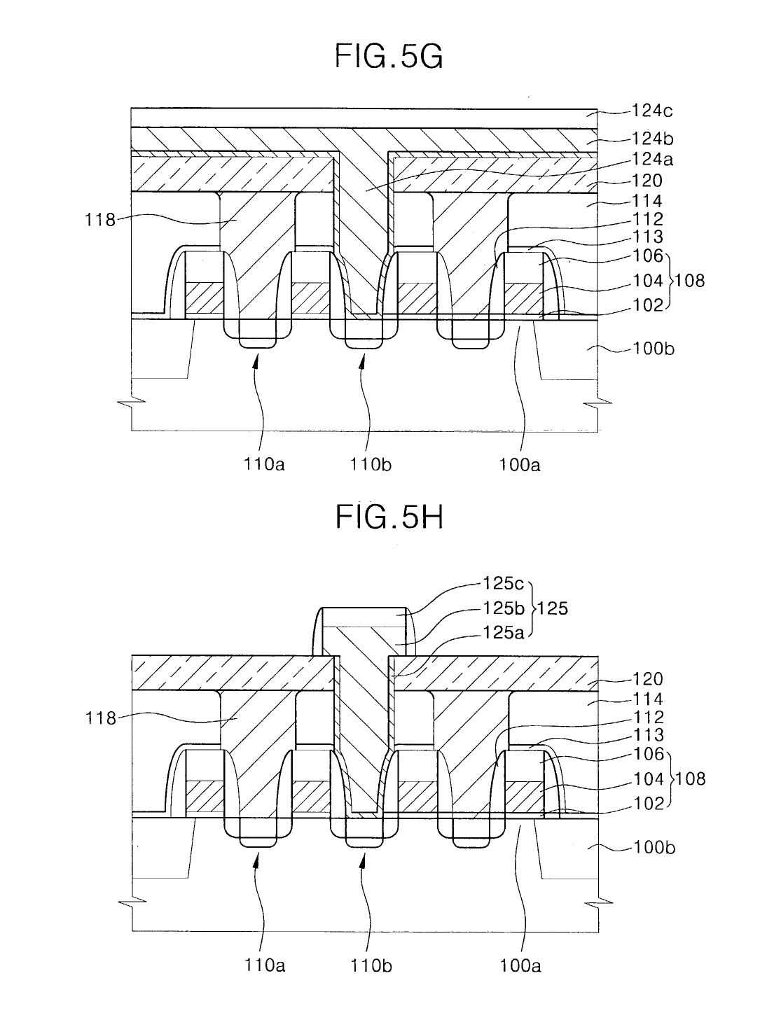

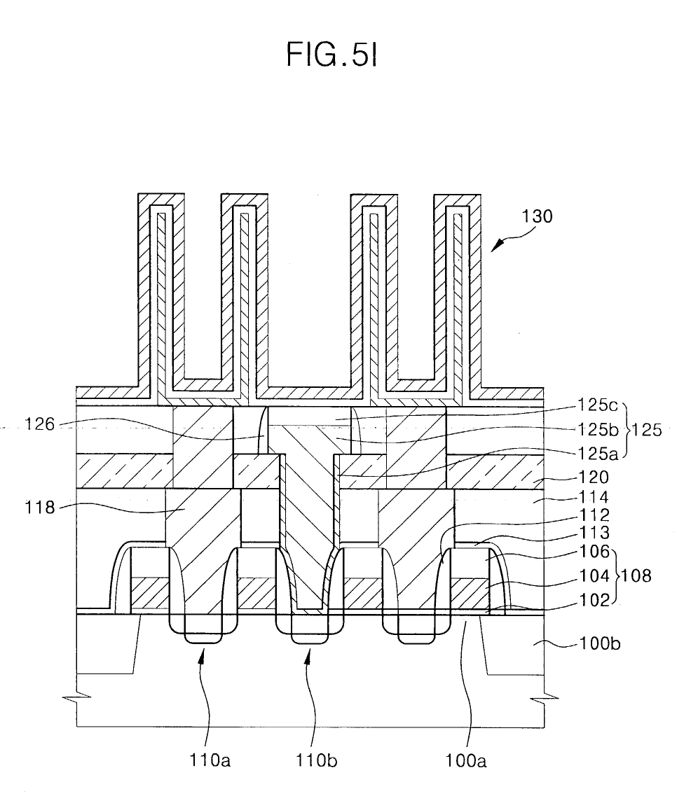

Active regions 100a define regions where cells and peripheral circuits are formed and FIGS. 5A to 5I are cross-sectional views illustrating a method of manufacturing the DRAM device according to one embodiment of the present invention.

Structures 108 used as gate electrodes are disposed in the form of line elongated in a Y-direction.

Source and drain regions 110a and 110b are located in the active regions 100a with the gate structures 108 interposed therebetween. That is, one drain region 110b and two source regions 110a are provided in one active region 100a having an island shape. Accordingly, in one active region 100a, there are formed two unit cells consisting of common drain region 110b, two source regions 110a and two gate structures 108. Bit lines 125 are formed in an X-direction so as to make direct contact with the drain region 110b of each group and to electrically connect the drain regions 110b to each other.

A vertical structure of the DRAM device will be described with the reference to FIG. 4.

Gate structures 108 are formed on a substrate divided into active regions 100a and field regions 100b, each of the gate structures 108 having a gate insulating layer pattern 102, a conductive layer pattern 104 and a first nitride layer pattern 106 that are stacked successively. Source/drain regions 110a and 110b formed by impurity doping are located below the surface of the substrate adjacent to both sidewalls of each of the gate structures 108. First nitride spacers 112 are formed on both sidewalls of each of the gate structures 108.

A first insulating interlayer 114 having first contact holes exposing each of the source drain regions 10a are provided so as to cover the gate structures 108. Source pad electrodes 118 are formed in each of the first contact holes and connected to the corresponding source regions 110a. The source pad electrode 118 comprises a polysilicon film or a metal film such as a tungsten film, an aluminum film or a copper film. The upper surfaces of the source pad electrode 118 and the first insulating interlayer 114 are located at the same height.

A second insulating interlayer 120 is formed on the source pad electrodes 118 and the first insulating interlayer 114. Bit lines 125 are formed on the second insulating interlayer 120 so as to fill up second contact holes that are formed to pass through the first and second insulating interlayer 114 and 120 and expose each of the drain regions 10b. Here, the bit lines 125 are formed so as to be isolated from the source pad electrodes 118 and the gate structures 108. Each of the bit lines 125 has a barrier metal layer 125a and a metal layer 125b. The barrier metal layer 125a that makes contact with the drain region 110b is formed from at least one film selected from the groups consisting of a cobalt silicide film, a titanium silicide film, a titanium nitride silicide film, a tantalum silicide film and a titanium nitride silicide film. The metal layer 125b stacked on the barrier metal layer 125a is formed from a material such as tungsten, aluminum, copper, etc. Second nitride patterns 125c are formed on the top of each of the bit lines 125. Second nitride spacers 126 are formed on the sidewalls of each of the bit lines 125 located on the second insulating interlayer 120.

Upon each of the source pad electrodes 118, there are formed capacitors 130 connected to the corresponding source pad electrodes 118. The capacitors 130 are formed so as to be electrically out of contact with (that is, be electrically isolated from) the bit lines 125.

FIGS. 5A to 5I are cross-sectional views illustrating a method of manufacturing the DRAM device according to one embodiment of the present invention.

Referring to FIG. 5A, an isolation process is carried out on a semiconductor substrate to divide the substrate into active regions 100a and field regions 100b. The active regions 100a have the island shape of diagonal direction (see FIG. 3).

A gate insulating layer pattern 102, a conductive layer pattern 104 and a first nitride layer pattern 106 are successively stacked on the semiconductor substrate in which the active regions 106 are defined, thereby forming gate structures 108. The gate structures 108 are disposed in the form of line elongated in a Y-direction. The gate structures 108 are formed such that two gate structures 108 go through one island type active region 100a.

Next, using the gate structures 108 as an ion implantation mask, an impurity of low concentration is ion-implanted in the substrate to form lightly doped source/drain regions below the surface of the substrate on both sides of the gate structures 108.

First nitride spacers 112 are formed on the sidewalls of each of the gate structures 108. The first nitride spacers 112 serve to form highly doped source/drain regions of the LDD (lightly-doped drain) structure and self-aligned contact holes.

Then, after forming an etch stopping layer 113 comprising a thin nitride film of about 100 Å on the gate structures 108 and the surface of the substrate, an impurity of low concentration is ion-implanted below the surface of the substrate located between the first nitride spacers 112, thereby forming the highly doped source and drain regions 110a and 110b of LDD structure.

Referring to FIG. 5B, a first insulating interlayer 114 is formed to cover the gate structures 108.

However, as the design rule of the semiconductor device decreases, the space between the gate structures 108 becomes smaller and narrower. Further, since the first nitride spacers 112 are formed on the both sidewalls of each of the gate structures 108, a portion to be filled with the first insulating interlayer 114 becomes more smaller and narrower as twice as the horizontal thickness of the first nitride spacer 112. So, it is very difficult to fill up the small-sized portion with an insulating material without the generation of voids. Accordingly, a film capable of being used as the first insulating interlayer 114 is restricted to an oxide film having a good gap fill property. Specifically, the first insulating interlayer 114 can comprise a reflowable oxide film such as BPSG (borophosphosilicate glass), SOG (spin-on glass), etc. or a high density plasma (HDP) oxide film.

Among these films, the gap filling property of BPSG film varies with the concentration of boron (B) and phosphorous (P). That is, as the concentration of B and P in the BPSG film increases, the gap filling property becomes good to fill up the small-sized space between the gate structures 108 without voids. Therefore, in case of depositing the BPSG film as the first insulating interlayer 114, there is used a heavily doped BPSG film with boron (B) and phosphorous (P). However, as the concentration of B and P in the BPSG film increases, the BPSG film is consumed during a subsequent cleaning process because the bonds of atoms constituting the film become loose.

Referring to FIG. 5C, a portion of the first insulating interlayer 114 is etched away and continuously, the underlying etch stopping layer 113 is etched away to form first self-aligned contact holes 116 exposing each of the source regions 110a.

Particularly, a photoresist is coated on the first insulating interlayer 114. A photo process is carried out on the photoresist so as to selectively open predetermined portions located on the source regions 110a, thereby forming photoresist patterns. Using the photoresist patterns as an etching mask, the first insulating interlayer 114 is etched away under a condition where the first nitride spacers 112 and the first nitride layer pattern 106 are hardly etched away. When the first insulating interlayer 114 is completely etched to expose the underlying etch stopping layer 113, the exposed etch stopping layer 113 is etched away to form the first self-aligned contact holes 116 exposing the source regions 110a.

Referring to FIG. 5D, a first cleaning process is carried out to remove polymers and native oxide layers formed on the bottom of the first self-aligned contact holes 116. The cleaning process removes a portion of the first insulating interlayer 114 exposed to the sides of the first contact holes 116, as well as the native oxide layers formed on the bottom of the first contact holes 116. Particularly, the first insulating interlayer 114 located on the top of the first contact holes 116 is most rapidly consumed because a cleaning solution used for the cleaning process acts simultaneously on the sides of the first contact holes 116 and the upper side of the first insulating interlayer 114 to perform the etching (as shown by arrows in portion B). In addition, the neighboring contact holes are easy to be connected to each other because the first contact holes 116 are formed such that the upper open region thereof is wider than the lower open region thereof.

However, when performing the process of forming the first contact holes 116, only contact holes exposing the source regions 110a are formed without forming contact holes exposing the drain regions 110b in the way of the conventional method. Accordingly, the number of the contact holes formed by the process of forming the first contact holes 116 is reduced to about ⅓ as compared to the conventional method and the space between the first contact holes increases. So, during the cleaning process, the probability of generating failures where the contact holes are bridged with each other decrease.

Next, the inside of the first self-aligned contact holes 116 cleaned by the above cleaning process is filled up with a conductive material. The conductive material is etched back until the top surface of the first insulating interlayer 114 is exposed, thereby forming source pad electrodes 118 partially connected to the source regions 110a. Here, a chemical mechanical polishing process or an overall etching process may be performed instead of the etch-back process. The conductive material comprises polysilicon, tungsten, aluminum, copper, etc. These conductive material may be used alone or in a combination thereof. Referring to FIG. 5E, a second insulating interlayer 120 is formed on the source pad electrodes 118 and the first insulating interlayer 114.

The second insulating interlayer 114 may be not formed of a silicon oxide film having a good gap fill property as the first insulating interlayer 114 because the second insulating interlayer 114 is formed on the first insulating interlayer 114 and the source pad electrodes 118 planarized by the etch back process. Therefore, the second insulating interlayer 120 is formed from a film having atomic bonds denser than those of the first insulating interlayer 114, so that a portion of the second insulating interlayer 120 is not removed or damaged during a subsequent process. Particularly, it is preferred that the second insulating interlayer 120 is formed from an oxide layer having an etching rate lower than that of the first insulating interlayer 114 when the substrate is treated with the same cleaning solution. If the second insulating interlayer 120 is formed from a BPSG film, the second insulating interlayer 120 is formed such that the concentration of boron and phosphorous is lower than the first insulating interlayer 114.

Referring to FIG. 5F, a portion of the second and first insulating interlayer 120 and 114 are successively etched away to form second self-aligned contact holes 122 partially exposing the substrate where the drain regions 110b are formed.

Particularly, a photoresist is coated on the second insulating interlayer 120. A photo process is carried out on the coated photoresist so as to selectively open predetermined portions located on the drain regions 110b, thereby forming photoresist patterns (not shown). Using the photoresist patterns as an etching mask, the second insulating interlayer 120 and the first insulating interlayer 114 are successively etched away under a condition where the first nitride spacers 112 and the first nitride layer pattern 106 are hardly etched away. When the first insulating interlayer 114 is completely etched to expose the underlying etch stopping layer 113, the exposed etch stopping layer 113 is etched away to form the second self-aligned contact holes 122 exposing each of the drain regions 110b.

Referring to FIG. 5G, a second cleaning process is carried out to remove polymers and native oxide layers formed on the bottom of the second self-aligned contact holes 122.

When performing the second cleaning process, the second insulating interlayer 120 hardly etched by the cleaning process is exposed in the neighborhood of the upper portions of the second self-aligned contact holes 122. So, the size of the open region located on the second contact holes 122 scarcely increases though the second cleaning process is executed. Further, the second contact hole 122 is formed such that the top thereof is higher than that of the first contact hole 116 and the depth thereof is deeper than that of the first contact hole 116. So, the second contact hole 122 is not opposite to the source pad electrode 118 near the top of the second contact hole 122. Accordingly, even through the upper open regions of the second contact holes 122 become wider, there are hardly generated bridges between the source pad electrode 118 and a conductive material to be formed in the second contact holes 122.

Next, a barrier metal layer 124a is formed to be thin to have a thickness of about 100˜300 Å in the second self-aligned contact holes 122 and on the second insulating interlayer 120. The barrier metal layer 124a comprises at least one material selected from the groups consisting of cobalt, titanium, titanium nitride, tantalum and tantalum nitride. Here, the substrate made of silicon is exposed under the second self-aligned contact holes 122. Therefore, when forming the barrier metal layer 124a with the above material, a film such that a cobalt silicide film, a titanium silicide film, a titanium nitride silicide film, a tantalum silicide film or a tantalum nitride silicide film is formed on the bottom surface of the second contact holes 122 in accordance with the deposited material.

Then, a metal layer 124b is deposited so as to fill up the second self-aligned contact holes 122 on which the barrier metal layer 124a is formed. Here, the metal layer 124b is formed so as to have a thickness of about 1000˜3000 Å when it is measured from the barrier metal layer 124a located on the second insulating interlayer 120. The metal layer 124b comprises tungsten, aluminum or copper.

Next, a second silicon nitride layer 124c is formed on the metal layer 124b.

Referring to FIG. 5H, the second silicon nitride layer 124c and the metal material formed on the second insulating interlayer 120 are partially etched away to form bit lines 125 that make direct contact with the drain region of each group and electrically connect the drain regions with each other. The bit lines 125 are formed in a direction perpendicular to the gate structures 108.

Then, second nitride spacers 126 for protecting the bit lines 125 are formed on the sidewalls of each of the bit lines 125.

The bit lines 125 are formed to make direct contact with the drain regions 110b. That is, no pad electrode for connecting the drain region 110b to the bit line 125 is formed between the drain region 110b and the bit line 125 as executed in the conventional method, resulting in the decrease in the contact resistance generated by the pad electrode. In addition, the resistance between the drain region 10b and the bit line 125 is more reduced because the bit line 125 is formed from a metal material having a relatively lower resistance than the other materials.

Accordingly, the generation of the operation failures due to the increase in the contact resistance between the bit line 125 and the drain region 110b may be minimized. Particularly, since the problem of increasing the contact resistance becomes aggravated as the contact area to the drain region decreases with the scaling down of the design rule of the semiconductor device, it is concluded that the effect of the decrease in the contact resistance caused by the above process becomes considerable.

Referring to FIG. 5I, capacitors 130 connected to each of the source pad electrodes 118 are formed on the corresponding source pad electrodes 118.

By doing these steps, a semiconductor device including transistors is formed while minimizing the process failures.

Although the present embodiment illustrates the cell layout and manufacturing process capable of applying to DRAM devices, it is apparent that the present invention can apply variously to semiconductor devices including transistors.

According to the present invention, the semiconductor device includes the lines for signal transmission comprising the metal material and directly connected to the drain regions. So, a contact resistance between the drain region and the line for signal transmission can be minimized because the metal material has a relatively low resistance than the other materials.

Although many embodiments of the present invention have been described, it is understood that the present invention should not be limited to these preferred embodiments but various changes and modifications can be made by one skilled in the art within the spirit and scope of the present invention as hereinafter claimed.

What is claimed is:

1. A semiconductor device comprising:
gate structures having two sidewalls formed on a semiconductor substrate, each of the gate structures having a gate insulating layer pattern, a conductive layer pattern and a nitride layer pattern that are stacked successively;
nitride spacers formed on both sidewalls of each of the gate structures;
source/drain regions formed at surface portions of the substrate adjacent to both sidewalls of each of the gate structures, forming a resultant structure;
first insulating interlayer formed on the resultant structure, the first insulating interlayer having first contact holes exposing the source regions;
source pad electrodes formed in each of the first contact holes and connected to the corresponding source regions;
a second insulating interlayer formed on the first insulating interlayer; and
metal lines for signal transmission formed on the second insulating interlayer so as to fill up second contact holes that pass through the first and second insulating interlayer, the second contact holes exposing each of the drain regions.

2. The device as claimed in claim 1, wherein the metal lines further comprise a barrier metal layer and a metal layer stacked successively.

3. The device as claimed in claim 2, wherein the barrier metal layer makes direct contact with the drain region further comprises at least one selected from the group consisting of a cobalt silicide film, a titanium silicide film, a titanium nitride silicide film, a tantalum silicide film and a tantalum nitride silicide film.

4. The device as claimed in claim 2, wherein the metal layer comprises at least one selected from the groups consisting of tungsten, aluminum and copper.

5. The device as claimed in claim 1, further comprising nitride patterns, formed on the surface of each of the metal lines, to protect the metal lines.

6. The device as claimed in claim 1, wherein the source pad electrode comprises at least one selected from the groups consisting of polysilicon film, tungsten film, aluminum film, and copper film.

7. The device as claimed in claim 1, further comprising capacitors connected to each of the source pad electrodes.

8. A method of manufacturing a semiconductor device comprising:
forming gate structures on a semiconductor substrate, each of the gate structures including a gate insulating layer pattern, a conductive layer pattern and a nitride layer pattern that are stacked successively;
implanting an impurity below the surface of the substrate by using the gate structures as a mask to form source and drain regions;
forming nitride spacers on both sidewalls of each of the gate structures;
forming a first insulating interlayer so as to cover the gate structures;
etching a portion of the first insulating interlayer to form first contact holes partially exposing the substrate where the source regions are formed;
filling the first contact holes with a conductive material to form source pad electrodes electrically connected to the exposed source regions in the source regions;
forming a second insulating interlayer on the first insulating interlayer;
subsequently etching a portion of the second insulating interlayer and the first insulating interlayer to form second contact holes exposing the substrate where the drain regions are formed;
depositing a metal material in the second contact holes and on the second insulating interlayer; and
etching a portion of the metal material formed on the second insulating interlayer to form metal lines for signal transmission, the metal lines making direct contact with the drain region of each group to electrically connect the drain regions to each other, while being isolated from the source pad electrodes.

9. The method as claimed in claim 8, wherein forming the first insulating interlayer further comprises forming a BPSG film, a SOG film or a HDP oxide film.

10. The method as claimed in claim 8, further comprising cleaning the substrate including the first contact holes prior to filling the first contact holes with the conductive material to form the source pad electrodes.

11. The method as claimed in claim 8, wherein forming the second insulating interlayer further comprise forming an oxide film having an etch rate slower than that of the first insulating interlayer when the substrate is treated with a same cleaning solution.

12. The method as claimed in claim 8, further comprising cleaning the substrate including the second contact holes prior to depositing the metal material in the second contact holes and on the second insulating interlayer.

13. The method as claimed in claim 8, wherein depositing the metal materialfurther comprises:
forming a barrier metal layer on the side and bottom of the second contact holes and the top of the second insulating interlayer; and
forming a metal layer so as to fill up the second contact holes.

14. The method as claimed in claim 13, wherein forming the barrier metal layer formed on the bottom of the second contact holes further comprises forming at least one film selected from the group consisting of a cobalt silicide film, a titanium silicide film, a titanium nitride silicide film, a tantalum silicide film and a tantalum nitride silicide film.

15. The method as claimed in claim 13, wherein depositing the metal layer comprises depositing at least one material selected from the groups consisting of tungsten, aluminum and copper.

16. The method as claimed in claim 8, further comprising forming a nitride layer on the metal material after depositing the metal material.

17. The method as claimed in claim 8, further comprising forming spacers for protecting the metal lines on the sidewalls of each of the metal lines after etching the metal material to form the metal lines.

18. The method as claimed in claim 8, wherein filling the first contact holes with a conductive material to form the source pad electrode further comprises filling the first contact holes with at least one film selected from the groups consisting of a polysilicon film, a tungsten film, an aluminum film and a copper film.

19. The method as claimed in claim 8, further comprising forming capacitors connected to each of the source pad electrodes after forming the metal lines.

20. A method of manufacturing a semiconductor device comprising:
forming gate structures on a semiconductor substrate, each of the gate structures including a gate insulating layer pattern, a conductive layer pattern and a nitride layer pattern that are stacked successively;
implanting an impurity below the surface of the substrate by using the gate structures as a mask to form source and drain regions;
forming nitride spacers on both sidewalls of each of the gate structures;
forming a first insulating interlayer so as to cover the gate structures;
etching a portion of the first insulating interlayer to form first contact holes partially exposing the substrate where the source regions are formed;
filling the first contact holes with a conductive material to form source pad electrodes electrically connected to the exposed source regions in the source regions;
forming a second insulating interlayer on the first insulating interlayer;
subsequently etching a portion of the second insulating interlayer and the first insulating interlayer to form second contact holes exposing the substrate where the drain regions are formed;
depositing a metal material in the second contact holes and on the second insulating interlayer;
etching a portion of the metal material formed on the second insulating interlayer to form bit lines, the bit lines making direct contact with the drain region of each group to electrically connect the drain regions to each other, while being isolated from the source pad electrodes; and
forming capacitors on each of the source pad electrodes, the capacitors making contact with the corresponding the source pad electrodes.

21. The method as claimed in claim 20, wherein depositing the metal materialfurther comprises:
forming a barrier metal layer on the side and bottom of the second contact holes and the top of the second insulating interlayer; and
forming a metal layer so as to fill up the second contact holes.

22. The method as claimed in claim 11, wherein forming the second insulating layer further comprises forming a BPSG film having a lower concentration of boron on phosphorous than the first insulating layer.

23. The device as claimed in claim 1, wherein the second contact holes have tops that are higher than the first contact holes.

24. The method of claim 8, wherein etching a portion of the second insulating layer and the first insulating layer to form second contact holes further comprises etching a portion of the second insulating layer and the first insulating layer to form second contact holes having tops higher than the first contact holes
